(19) United States
(12) Patent Application Publication
(10) Pub. No.: US 2009/0168386 A1
(43) Pub. Date: Jul. 2, 2009

(54) ELECTRONIC APPARATUS AND SUBSTRATE MOUNTING METHOD

(75) Inventors: Daigo Suzuki, Yokahama-shi (JP); Akihiko Happoya, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/248,748

(22) Filed: Oct. 9, 2008

(30) Foreign Application Priority Data
Dec. 27, 2007 (JP) 2007-337802

(51) Int. Cl. H05K 7/02; H01L 21/52

(52) U.S. Cl. 361/810; 438/106; 257/E21.5

(57) ABSTRACT

According to one embodiment, an electronic apparatus comprises a frame with a hollow portion formed inside thereof, a shield coating applied to the inner surface of the frame, a plurality of connection terminals having lead portions provided on the outside surface of the frame, and a module substrate which mounts circuit components on the front and rear surfaces thereof and which is placed on the frame in a state where at least the rear side circuit components are housed in the hollow portion with the circuit components on the front and rear surfaces connected to the connection terminals.

### CROSS-REFERENCE TO RELATED APPLICATIONS

This application is based upon and claims the benefit of priority from Japanese Patent Application No. 2007-337802, filed Dec. 27, 2007, the entire contents of which are incorporated herein by reference.

### BACKGROUND

1. Field

One embodiment of the present invention relates to an electronic apparatus and a substrate mounting method applied to a circuit section for processing a high-frequency signal.

2. Description of the Related Art

In a circuit board constituting an electronic circuit, a substrate mounting technique in which circuit components are mounted on both sides of a small substrate to obtain a module substrate and the obtained module substrate is mounted, as an electronic component (mounting component), on a unit substrate using a multi-layer printed circuit board is used as a means for enabling high-density mounting.

Conventionally, the above substrate mounting technique has been realized using a spacer having a terminal structure using penetrating pins or a connector mechanism. In a configuration using the spacer, a spacer having penetrating pins arranged at a certain interval on a strip-shaped resin structure is used to support the module substrate on the unit substrate with the penetrating pins used as connection terminals between the substrates. In the substrate mounting technique using the connector mechanism, connector pairs (connector plugs and connector receptacles) which are respectively connected to each other are provided on both the unit substrate and module substrate to support the module substrate on the unit substrate.

Since the substrate mounting technique using the spacer employs a mounting structure in which penetrating holes for receiving the penetrating pins are formed in both the module substrate and unit substrate and the penetrating pins are soldered to respective penetrating holes, so that a special mounting technique is required for fitting of the spacer and the mounting structure becomes complicated, thus causing problems in terms of productivity and yield. Further, a wiring cannot be laid out, across a plurality of layers, at the portions through which the penetrating pins penetrate in both the module substrate and unit substrate, restricting the wiring density, which may lead to an increase in the substrate size. In the substrate mounting technique using the connectors, it is necessary to ensure a mounting space for the connector pairs (connector plugs and connector receptacles) both in the module substrate and unit substrate, thus preventing in a reduction in the size and weight of the substrate structure and causing problems in terms of productivity, yield, and production cost.

Further, in the case where, in a module substrate that processes a high-frequency and high-speed operating signal, it is necessary to electro-magnetically shield the circuit components mounted on the surface of the module substrate that is opposed to the surface of the unit substrate, an additionally prepared shield cover is provided between the module substrate and unit substrate to thereby electro-magnetically shield the circuit components, thus making the above problems more pronounced.

As another substrate mounting technique requiring the electromagnetic shield, there is known a technique employing the following structure. That is, a wall member is provided in a gap between upper and lower substrates, and substrate wirings formed on respective surfaces of the upper and lower substrates are interconnected by a conductor formed on the wall member. Further, a holding groove for a sheet-metal member and a plated layer are formed on the side surfaces of the wall member on which the conductor is not formed, and the circuit components mounted on the lower substrate are electro-magnetically shielded by the metal-sheet member fitted to the holding groove and plated layer (refer to, e.g., Jpn. Pat. Appln. Publication No. 2006-156885).

However, this substrate mounting technique may lead to an increase in the number of components to be mounted and number of assembly man-hours, resulting in poor productivity and yield.

As described above, there is no substrate mounting technique realizing both satisfactory productivity/yield and easy practical application with respect to the module substrate mounting circuit components on both sides thereof.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exploded perspective view showing a configuration of the main part of an electronic apparatus according to a first embodiment of the present invention;

FIG. 2 is a perspective view showing a configuration of the main part of the electronic apparatus according to the first embodiment;

FIG. 3 is a perspective view showing an assembling process of the electronic apparatus according to the first embodiment;

FIG. 4 is a perspective view showing an assembling process of the electronic apparatus according to the first embodiment;

FIG. 5 is a perspective view showing an assembling process of the electronic apparatus according to the first embodiment;

FIG. 6 is a perspective view showing an assembling process of the electronic apparatus according to the first embodiment;

FIG. 7 is a side cross-sectional view showing an assembling process of the electronic apparatus according to the first embodiment;

FIG. 8 is a side cross-sectional view showing an assembling process of the electronic apparatus according to the first embodiment;

FIG. 9 is a side cross-sectional view showing an assembling process of the electronic apparatus according to the first embodiment;

FIG. 10 is a side cross-sectional view showing an assembling process of the electronic apparatus according to the first embodiment;

FIG. 11 is a side cross-sectional view showing another configuration example of the electronic apparatus according to the first embodiment;

FIG. 12 is a side cross-sectional view showing another configuration example of the electronic apparatus according to the first embodiment;

FIG. 13 is a side cross-sectional view showing another configuration example of the electronic apparatus according to the first embodiment;

FIG. 14 is a side cross-sectional view showing another configuration example of the electronic apparatus according to the first embodiment;

FIG. 15 is an exploded perspective view showing a configuration of the main part of an electronic apparatus according to a second embodiment of the present invention;

FIG. 16 is a side cross-sectional view showing another configuration example of the electronic apparatus according to the second embodiment;

FIG. 17 is a side cross-sectional view showing another configuration example of the electronic apparatus according to the second embodiment;

FIG. 18 is a side cross-sectional view showing another configuration example of the electronic apparatus according to the second embodiment;

FIG. 19 is a side cross-sectional view showing another configuration example of the electronic apparatus according to the second embodiment; and

FIG. 20 is a side cross-sectional view showing another configuration example of the electronic apparatus according to the second embodiment.

### DETAILED DESCRIPTION

Various embodiments according to the present invention will be hereinafter described with reference to the accompanying drawings. In general, according to one embodiment of the invention, an electronic apparatus comprising: a frame having a hollow portion inside thereof; a shield coating which is applied to the inner surface of the frame; a plurality of connection terminals which have lead portions provided on the outside surface of the frame; and a module substrate which mounts circuit components on the front and rear surfaces thereof and which is placed on the frame in a state where the rear side circuit components are housed in the hollow portion with the circuit components on the front and rear surfaces connected to the connection terminals.

Hereinafter, embodiments of an electronic apparatus and substrate mounting method according to the invention will be described with reference to the accompanying drawings.

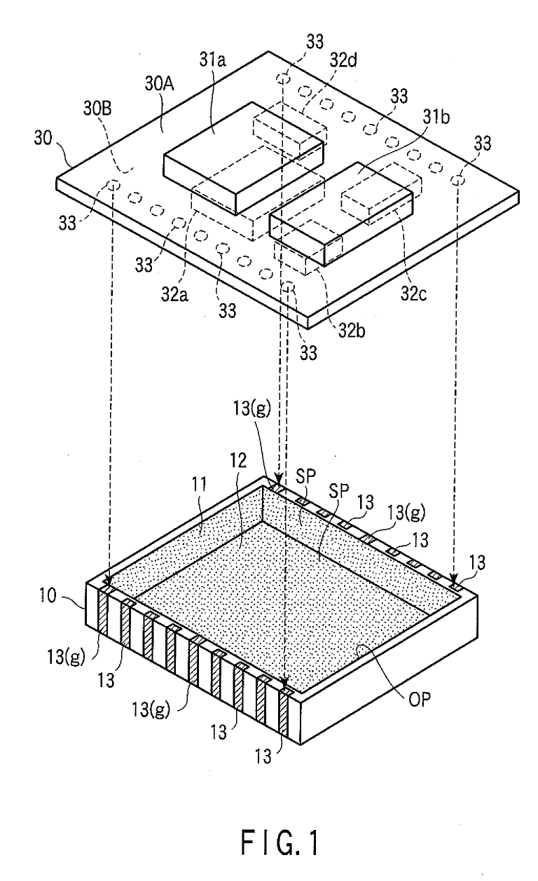

A first embodiment will be described with reference to FIGS. 1 to 10.

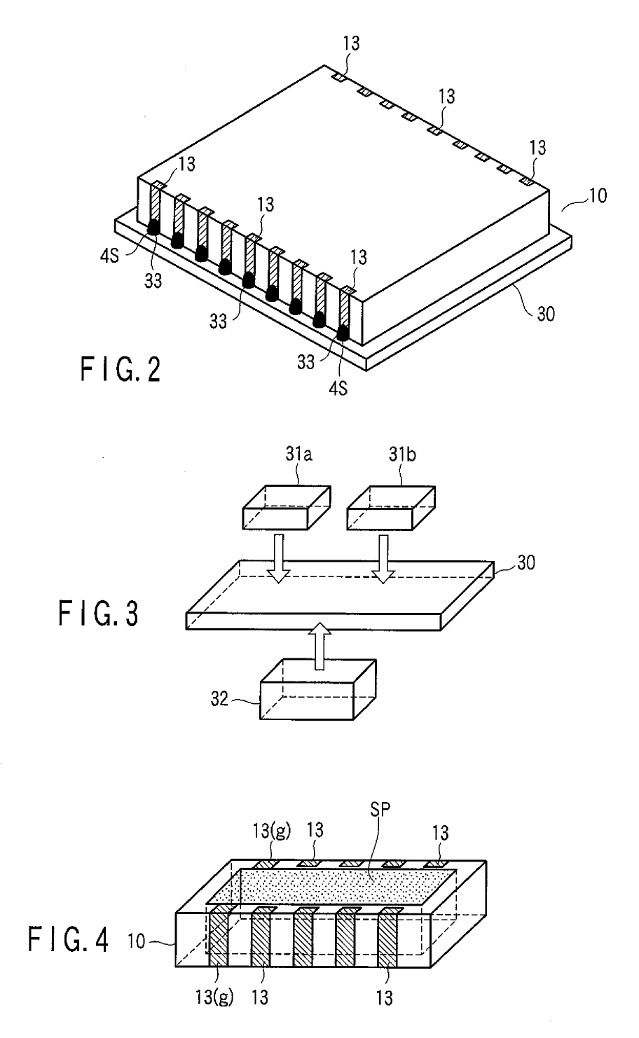

A configuration of the main part of an electronic apparatus according to the first embodiment of the present invention is shown in FIGS. 1 and 2. As shown in FIG. 1, the electronic apparatus according to the first embodiment of the present invention includes a frame 10 and a module substrate 30. The frame 10 is constituted by a frame-like portion 11 defining a hollow portion for component mounting, a shield coating SP applied to the inner surface of the frame-like portion 11, and a plurality of connection terminals 13 having lead portions on the outside surface of the frame-like portion 11. The module substrate 30 mounts circuit components 31a, 31b on a front surface 30A thereof and circuit components 32a, 32b, 32c, 32d on a rear surface 30B thereof. The module substrate 30 is placed on the frame 10 in a state where the circuit components 32a-32d on the rear surface are housed in the hollow portion for component mounting. In this state, the circuit components 32a-32d are connected to the connection terminals 13 through terminal connection pads 33.

The terminal connection pads 33 are so provided on the rear surface of the module substrate 30 as to correspond, in terms of position, to the plurality of connection terminals 13 provided on the frame 10 and are connected to the circuit components 31a, 31b and 32a-32d through a not shown wiring pattern. The circuit components 32a-32d mounted on the rear surface 30B of the module substrate 30 are high-frequency circuit components that process a high-frequency signal and require an electromagnetic shield. Although the plurality of circuit components 32a-32d are mounted on the rear surface 30B of the module substrate 30 in the embodiment shown in FIG. 1, the number and shape of the components are not especially limited. Further, the shape of the terminal connection pad 33 is not limited to that illustrated but it may be formed into a quadrangular shape, a polygonal shape, or an elliptical shape. Further, although the module substrate 30 is formed to have a slightly larger size than the frame shape of the frame-like portion 11 in the embodiment shown in FIG. 1, the size of the module substrate 30 may be made correspond to the size of the frame shape of the frame-like portion 11. Further, although a printed circuit board used as the module substrate 30 may be a multi-layer printed circuit board or a single-layer printed circuit board, the module substrate in this embodiment is constituted using a multi-layer printed circuit board having a ground (GND) plane and a power supply plane as is the case with the unit substrate the detail of which will be described later.

The frame 10 constitutes a support structure for supporting the module substrate 30. The connection terminals 13 are formed such that the edge portions thereof are exposed on the edge surface of the frame-like portion 11 of the frame 10 and, when the module substrate 30 is placed on the frame 10, the circuit components 31a, 31b and 32a-32d are connected to the connection terminals 13 through the terminal connection pads 33.

Some of the plurality of connection terminals 13 are used as ground (GND) terminals 13(g). The GND terminals 13(g) are extended to the shield coating SP applied to the inner surface of the frame-like portion 11 and are connected with the shield coating SP,

The frame-like portion 11 of the frame 10 has an opening portion OP on one (upper) side thereof and a closed portion 12 on the other (bottom) side thereof. The opening portion OP is closed by the module substrate 30 in a state where the module substrate 30 is placed on the frame 10.

The frame-like portion 11 and closed portion 12 are integrally formed by a resin into a box-like shaped casing portion with the closed portion 12 as the bottom surface.

The shield coating SP is applied to the entire inner surface of the casing portion constituted by the frame-like portion 11 and closed portion 12 by metal plating such as copper plating and, thus, the circuit components 32 mounted on the rear surface 30B of the module substrate 30 are housed in the casing portion such that they are electro-magnetically shielded by the grounded shield coating SP

A state where the terminal connection pads 33 provided on the rear surface of the module substrate 30 and connection terminals 13 formed to be exposed on the edge surface of the frame-like portion 11 of the frame 10 are soldered to each other to integrate the module substrate 30 and frame 10 is shown in FIG. 2. By integrating the module substrate 30 and frame 10 by means of the terminal connection, the module substrate 30 integrated with support members in which the high-frequency circuit components 32 are hermetically housed in the casing portion and electro-magnetically shielded is obtained. The module substrate 30 integrated with support members constitutes a single electronic component or an electronic apparatus having a specific function.

The module substrate 30 obtained by integrating the frame 10 therewith is mounted on a unit substrate to be described later as an electronic component (mounting component). The mounting of the module substrate 30 on the unit substrate is achieved by soldering the bottom portions of the connection terminals 13 provided on the frame-like portion 11 of the frame 10 to terminal connection pads (see reference numeral 4S of FIG. 10) to allow the module substrate 30 to be connected to the unit substrate (see reference numeral 1 of FIG. 10) through the connection terminal 13 of the frame 10, Details of the mounting of the module substrate 30 to the unit substrate 1 will be described later.

An assembling process and a substrate mounting process of the electronic apparatus according to the first embodiment are shown in FIGS. 3 to 10. FIGS. 2 to 6 are schematic perspective views showing respective assembling steps, and FIGS. 7 to 10 are schematic side cross-sectional views showing the same assembling steps as those shown in FIGS. 3 to 10.

Process A shown in FIGS. 3 and 7 is a component mounting process in the module substrate 30. Here, the circuit components 31a, 31b are mounted on the surface of the module substrate 30, and circuit components (only one component 32 is shown in this figure for the sake of simplicity) are mounted on the rear surface of the module substrate 30. Four circuit components 32a-32d are mounted in the case of FIG. 1.

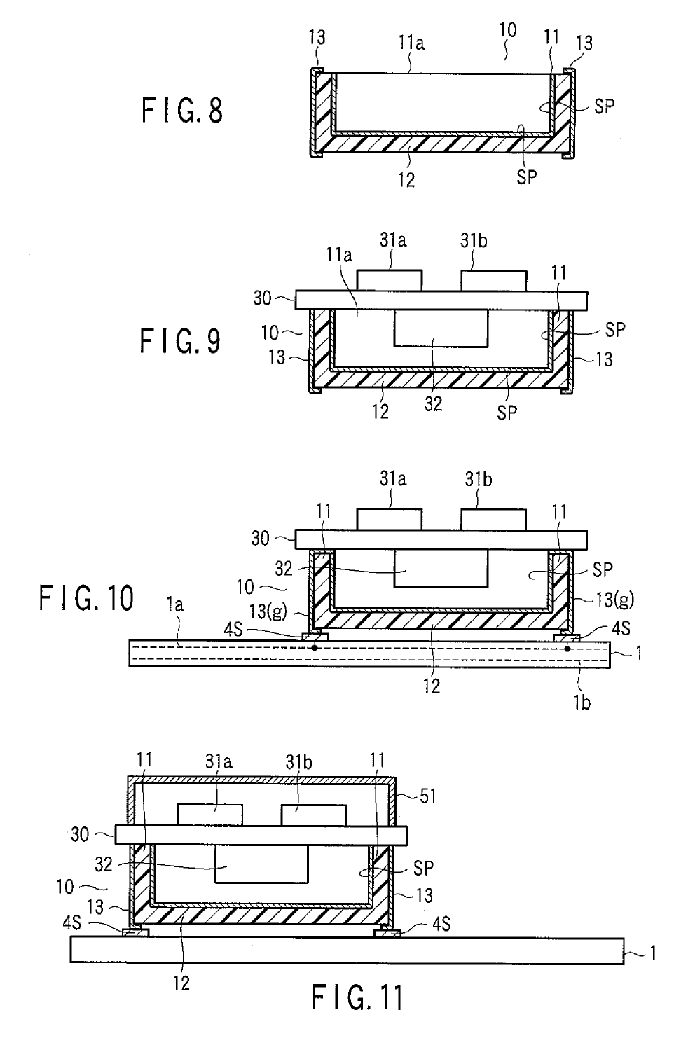

Process B shown in FIGS. 4 and 8 is a providing process of the frame 10 serving as a support structure for supporting the module substrate 30 on the unit substrate at a given height, where the frame 10 is provided as an attachment component to the module substrate 30. As shown in FIG. 1, the frame 10 is constituted by the frame-like portion 11 and closed portion 12 which define a hollow portion for component mounting, the shield coating SP applied to the inner surfaces of the frame-like portion 11 and closed portion 12, and the plurality of connection terminals 13 having lead portions on the outside surface of the frame-like portion 11.

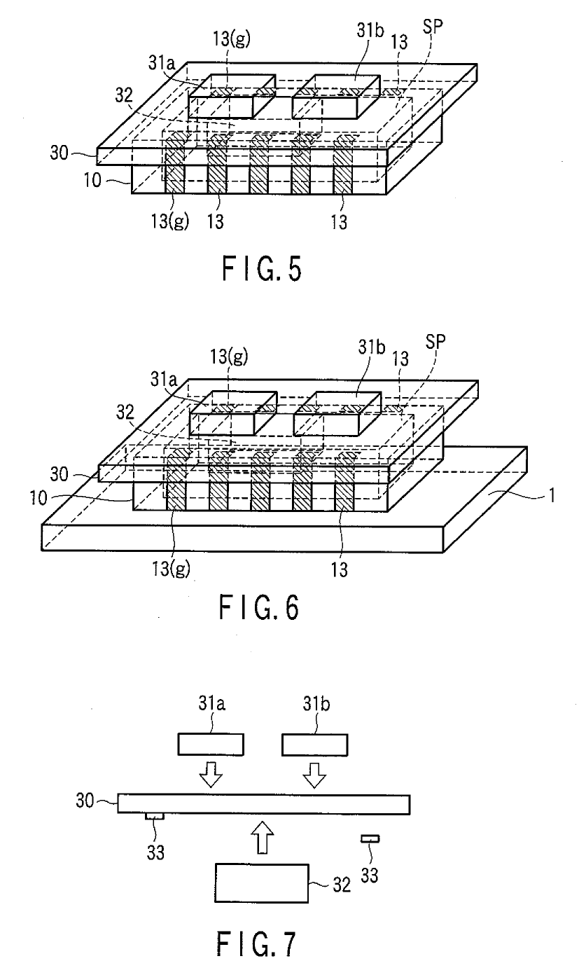

Process C shown in FIGS. 5 and 9 is a re-flow process of soldering the frame 10 to the module substrate 30. In the process C, the module substrate 30 is placed on the frame 10 in a state where the circuit components 32 (32a-32d in FIG. 1) on the rear surface are housed in the hollow portion 11a defined by the frame-like portion 11, and the connection terminals 13 of the frame 10 are soldered to the terminal connection pads 33 of the module substrate 30. As a result, the module substrate 30 and frame 10 are integrated with each other. In this state, the circuit components 31a, 31b, 32a-32d mounted on the module substrate 30 are connected to the connection terminals 13 through the terminal connection pads 33, and the high-frequency circuit components 32a-32d mounted on the rear surface of the module substrate 30 are hermetically housed in the hollow portion defined by the frame-like portion 11 of the frame 10 and electro-magnetically shielded.

Process D shown in FIGS. 6 and 10 is a re-flow process of soldering the components to the unit substrate 1, where the module substrate 30 integrated with the frame 10 is soldered to the unit substrate 1. By soldering the module substrate 30 to the unit substrate 1, the module substrate 30 is mounted on the unit substrate 1 in a state where it is supported by the frame 10, and circuit components 31a, 31b, 32 (32a-32d) mounted on the module substrate 30 are connected to the terminal connection pads 4S of the unit substrate 1 through the terminal connection pads 33 provided on the module substrate 30 and connection terminals 13 provided on the frame-like portion 11.

As described above, the module substrate 30 mounting the circuit components 31a, 31b, 32a-32d on both surfaces thereof can be mounted on the unit substrate 1 by using the frame 10 shown in FIG. 1. That is, it is possible to achieve the mounting of the module substrate 30 to the unit substrate 1 by a process eliminating the conventional complicated steps such as insertion of spacer pins to both the module substrate and unit substrate and attachment of connector members to both the substrates. Further, it is possible to electro-magnetically shield the high-frequency circuit components 32a-32d requiring electro-magnetic shield in a hermetically sealed structure without using a metallic member such as a shield case or shield plate as a mounting member, thereby providing reliable EMI shielding effect with respect to high-frequency components such as IC components for processing a high-speed signal operating at a low voltage to reliably suppress the influence caused by external noise. The unit substrate 1 may be constituted using a multi-layer printed circuit board and includes a ground layer (GND plane) la and a power supply layer (power supply plane) 1b as inner layers, as shown in FIG. 10. The shield coating SP applied to the inner surface of the frame-like portion 11 is circuit-connected to the GND plane 1a through the GND terminals 13(g) formed on the outer surface of the frame-like portion 11 and terminal connection pads 4S of the unit substrate 1.

Other examples of the substrate mounting structure using the frame 10 according to the first embodiment are shown in FIGS. 11 to 14. In FIGS. 11 to 14, the same reference numerals as those in FIGS. 1 to 10 denote the same or corresponding parts as those in FIGS. 1 to 10, and the descriptions thereof will be omitted here. Further, in FIGS. 11 to 14, the terminal connection pads 33 of the module substrate 30 and structure of the joint portion (soldered portion) of the frame-like portion 11 to the connection terminals 13 are omitted.

In the substrate mounting structure shown in FIG. 11, a shield case 51 is fitted on the module substrate 30 to thereby electro-magnetically shield the circuit components 31a, 31b mounted on the front surface of the module substrate 30 in addition to the circuit components 32 or components 32a-32d as shown in FIG. 1 mounted on the rear surface thereof. With this configuration, it is possible to electro-magnetically shield all the mounting components of the module substrate 30 by the frame 10 with the shield coating SP and the shield case 51, obtaining reliable EMI shielding effect.

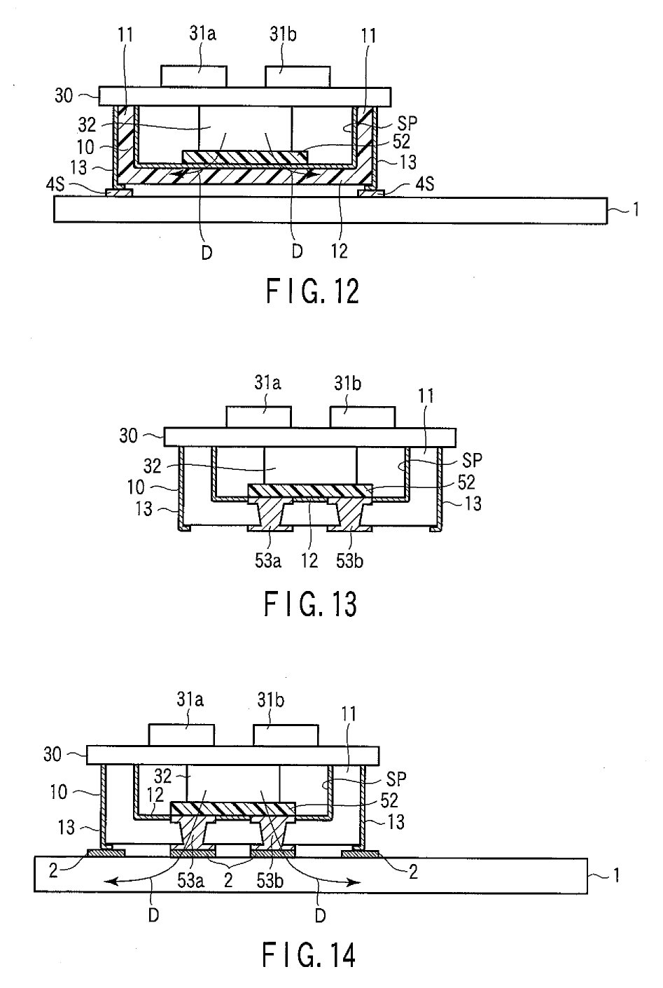

In the substrate mounting structure shown in FIG. 12, heat radiation paths D are formed in the circuit component 32 mounted on the rear surface of the module substrate 30. More specifically, a heat radiation member (e g., heat radiation grease or heat radiation sheet) 52 is interposed between the circuit component 32 and closed portion 12 of the frame 10 to thereby radiate heat generated from the circuit component 32 to outside through the heat radiation member 52 and frame 10 via the heat radiation paths D.

In the substrate mounting structure shown in FIG. 13, GND terminals are provided on the rear surface of the module substrate 30. More specifically, vias (e.g., laser via or through hole) 53a, 53b penetrating the closed portion 12 constituting the bottom of the frame 10 are provided in the closed portion 12, as GND terminals 53a, 53b to be brought into conduction with the shield coating SP and ground (GND) plane of the module substrate 30 are provided in the vias 53a, 53b. Further, the heat radiation member (e.g., heat radiation grease or heat radiation sheet) 52 is interposed between the circuit component 32 and closed portion 12 of the frame 10 to thereby radiate heat generated from the circuit component 32 to outside through the vias 53a, 53b constituting the GND terminals.

An example in which the module substrate 30 integrated with the frame 10 provided with the GND terminals (vias) 53a, 53b is mounted on the unit substrate 1 as an electronic component (mounting component) is shown in FIG. 14. In the substrate mounting structure shown in FIG. 14, the GND terminals 53a, 53b provided on the bottom portion of the frame 10 are soldered to wiring patterns 2 of the unit substrate 1. With this configuration, it is possible to connect the shield coating SP to the ground (GND) of the unit substrate 1 at a lower impedance, as well as to form the heat radiation paths D for radiating heat generated from the circuit component 32 mounted on the rear surface of the module substrate 30 to the outside through the heat radiation member 52, GND terminals (vias) 53a, 53b, and wiring patterns 2 of the unit substrate 1.

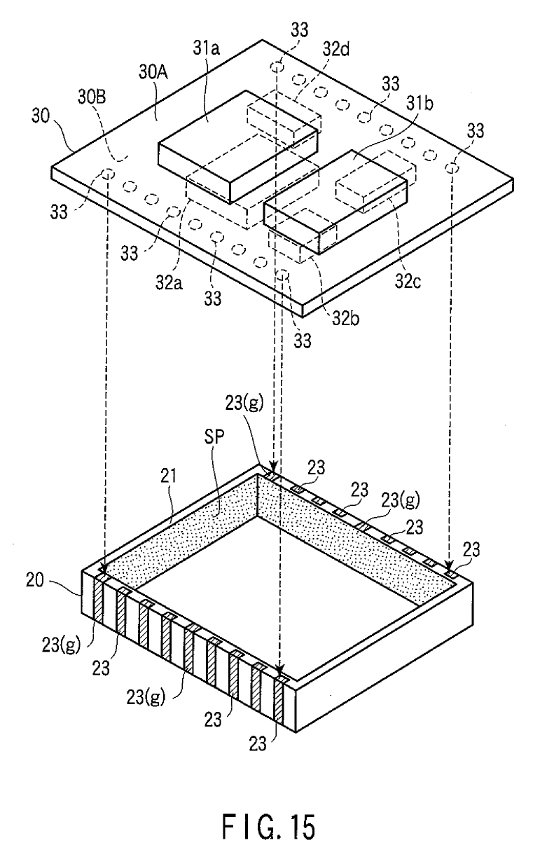

A configuration of the main part of an electronic apparatus according to a second embodiment of the present invention is shown in FIG. 15. A particularly different point of the second embodiment from the first embodiment is in that the frame 10 does not have the closed portion in the frame-like portion.

As shown in FIG. 15, the electronic apparatus according to the second embodiment includes a frame 20 and module substrate 30. The frame 20 is constituted by a frame-like portion 21 defining a hollow portion for component mounting, a shield coating SP applied to the inner surface of the frame-like portion 21, and a plurality of connection terminals 23 having lead portions on the outside surface of the frame-like portion 21. The module substrate 30 mounts circuit components 31a, 31b on a front surface 30A thereof and circuit components 32a-32d on a rear surface 30B thereof. The module substrate 30 is placed on the frame 20 in a state where the circuit components 32a-32d on the rear surface are housed in the hollow portion of the frame-like portion 21 for component mounting. In this state, the circuit components 32a-32d are connected to the connection terminals 23 through terminal connection pads 33.

The frame 20 has a rectangular frame-like portion 21 to constitute a support structure for supporting the module substrate 30. The connection terminals 23 are formed such that the edge portions thereof are exposed on the edge surface of the frame-like portion 21 of the frame 20 and, when the module substrate 30 is placed on the frame 20, the circuit components 31a, 31b, 32a-32d are connected to the connection terminals 23 through the terminal connection pads 33.

Some of the plurality of connection terminals 23 are used as ground (GND) terminals 23(g). The GND terminals 23(g) are extended to the shield coating SP applied to the inner surface of the frame-like portion 21 and are brought into connection with the shield coating SP.

The shield coating SP is applied to the entire inner surface of the rectangular frame-like portion 21 by metal plating such as copper plating and, thus, the circuit components 32a-32d mounted on the rear surface 30B of the module substrate 30 are housed in the hollow portion within the frame-like portion 21 in a state where the outer surfaces of the circuit components 32a-32d are electro-magnetically shielded by the shield coating SP.

By integrating the module substrate 30 and frame 20 by means of soldering between the terminal connection pads 33 provided on the rear surface of the module substrate 30 and connection terminals 23 exposed on the edge surface of the frame-like portion 21 of the frame 20, the module substrate 30 integrated with support members in which outer surfaces of the high-frequency circuit components 32a-32d are surrounded by the inner surface of the frame-like portion 21 to be electro-magnetically shielded is obtained. The module substrate 30 integrated with support members constitutes a single electronic component or an electronic apparatus having a specific function.

The module substrate 30 obtained by integrating with the frame 20 is mounted on the unit substrate 1 shown in FIG. 10 as an electronic component (mounting component). The mounting of the module substrate 30 on the unit substrate is achieved by soldering the bottom portions of the connection terminals 23 provided on the frame-like portion 21 of the frame 20 to terminal connection pads 4S to allow the module substrate 30 to be connected to the unit substrate 1 through the connection terminals 23 provided on the frame 20.

In the substrate mounting structure obtained by using the frame 20 according to the second embodiment, although the outer surfaces of the circuit components 32a-32d mounted on the rear surface 30B of the module substrate 30 are surrounded by the shield coating SP, the upper portions (surface portions of the circuit components 32a-32d opposite to the mounting surfaces thereof to the module substrate 30) of the circuit components 32a-32d are exposed from the frame-like portion 11 and are not electro-magnetically shielded. However, when the module substrate 30 is mounted on the unit substrate 1 in a state where it is supported by the frame 20, a portion of the circuit components 32a-32d that is not electro-magnetically shielded is electromagnetically shielded by the ground layer (GND plane) la or power supply layer (power supply plane) provided in the unit substrate 1 as an inner layer as shown in FIG. 10. Thus, by mounting the module substrate 30 integrated with the frame 20 on the unit substrate 1 shown in FIG. 10, the circuit component 32 can be electro-magnetically shielded. Typically, a multi-layered circuit board allowing high-density mounting includes, as an inner layer, a ground layer constituting a GND plane (solid pattern or non-etched pattern on GND side) and a power supply layer constituting a power supply plane (solid pattern or non-etched pattern on power supply side), as shown in FIG. 10. When the frame structure according to the second embodiment is applied to the multi-layered circuit board, satisfactory EMI shielding effect with respect to the circuit component 32 mounted on the rear surface of the module substrate 30 can be obtained.

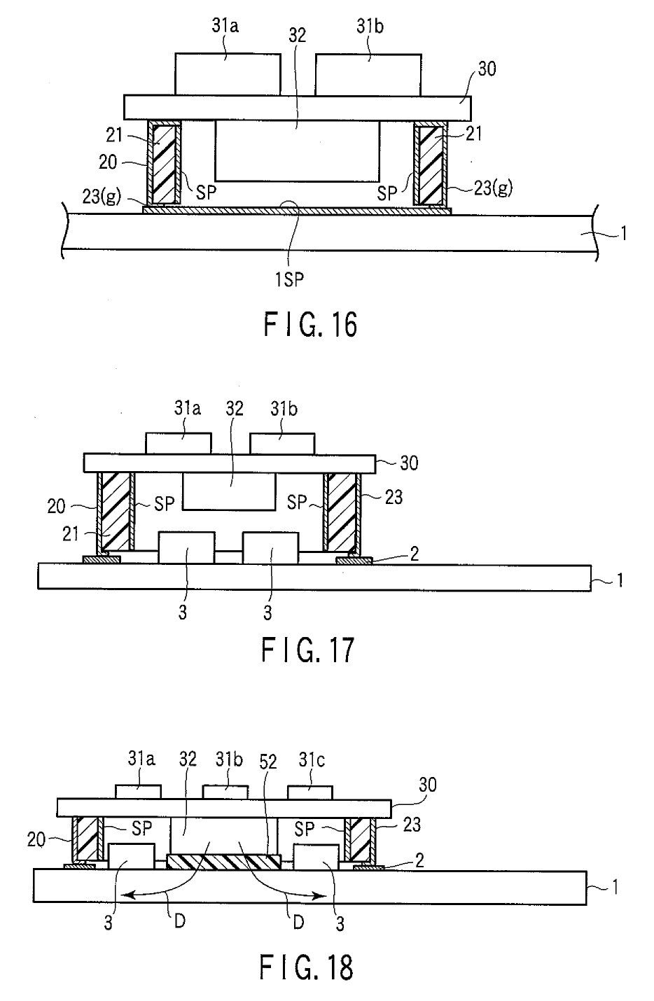

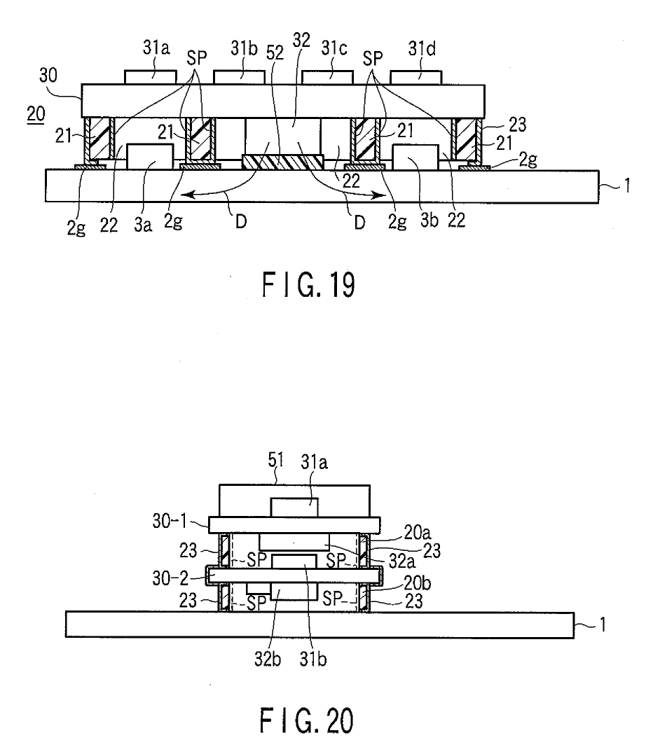

Other examples of the substrate mounting structure using the frame 20 according to the second embodiment are shown in FIGS. 16 to 20. In FIGS. 16 to 20, the same reference numerals as those in FIGS. 1 to 14 and FIG. 15 denote the same or corresponding parts as those in FIGS. 1 to 14 and FIG. 15, and the descriptions thereof will be omitted here. Further, in FIGS. 17 to 20, the terminal connection pads 33 of the module substrate 30 and structure of the joint portion (soldered portion) of the frame-like portion 21 to the connection terminals 23 are omitted.

In the substrate mounting structure shown in FIG. 16, a GND pattern 1SP is provided on the surface portion of the unit substrate 1 on which the frame 20 is mounted, avoiding soldered portions (terminal connection pads) of the connection terminals 23 (excluding GND terminals). At the time when the module substrate 30 integrated with the frame 20 is soldered to the unit substrate 1, the GND terminals 23(g) of the frame 20 are also soldered to the GND pattern 1SP. With this configuration, it is possible to electro-magnetically shield the circuit component 32 mounted on the rear surface of the module substrate 30 by surrounding the circuit component 32 by the shield coating SP applied to the inner surface of the frame-like portion 21 of the frame 20 and GNP pattern 1SP (that is, it is possible to house the high-frequency circuit component 32 in an electro-magnetically shielded chamber formed by the shield coating SP, GND pattern 1SP, and a not shown GND pattern of the multi-layered module substrate 30) and, thus, reliable EMI shielding effect can be obtained.

The electromagnetic shield can also be formed by using the ground layer (GND plane) 1a of the unit substrate 1 shown in FIG. 10 in the frame structure (frame-shaped structure) according to the second embodiment. However, by employing the electro-magnetic shielding structure shown in FIG. 16, it is possible to further enhance electro-magnetic shielding effect with respect to the circuit component 32 housed in the frame-like portion 21.

In the substrate mounting structure shown in FIG. 17, the frame 20 is used as a support mechanism for supporting the module 30, allowing circuit components 3 to be mounted in a portion on the unit substrate 1 that is surrounded by the frame 20.

The substrate mounting structure shown in FIG. 18 is a modification of the structure of FIG. 17, in which a heat radiation member 52 is interposed between the circuit component 32 mounted on the rear surface of the module substrate 30 and unit substrate 1 to thereby form heat radiation paths D for the circuit component 32.

In the substrate mounting structure shown in FIG, 19, a plurality of (four, in this case) frame-like portions 21 are used to constitute the frame 20, and the shield coating SP portions of the plurality of frame-like portions 21 are soldered to the ground patterns 2g of the unit substrate 1. As a result, the circuit component 32 mounted on the rear surface of the module substrate 30 and circuit components 3a, 3b mounted on the unit substrate 1 are enclosed in three spaces defined by four frame-like portions 21 and electro-magnetically shielded by the shield coating SP portions formed on the frame-like portions 21 Further, a heat radiation member 52 may be interposed between the circuit component 32 mounted on the rear surface of the module substrate 30 and unit substrate 1 to thereby form heat radiation paths D for the circuit component 32.

In the substrate mounting structure shown in FIG. 20, a plurality of (two, in this case) module substrates 30-1, 30-2 which are integrated with the frames 20a, 20b, respectively, are stuck to constitute a multistage module In the lower-stage module substrate 30-2, the circuit component 32b mounted on the rear surface thereof are electro-magnetically shielded by the shield coating SP of the lower-stage frame 20b, and circuit component 31b mounted on the front surface thereof are electro-magnetically shielded by the shield coating SP of the upper-stage frame 20a. In the upper-stage module substrate 30-1, the circuit component 32a mounted on the rear surface thereof are electro-magnetically shielded by the shield coating SP of the upper-stage frame 20a, and circuit component 31a mounted on the front surface thereof are electro-magnetically shielded by the shield case 51.

The present invention is not limited to the above embodiment, and can be variously modified without departing from the spirit and scope of the invention in practical use. For example, in the configurations shown in FIGS. 1, 10, 12 to 19, a shield case 51 (shield cap) as shown in FIG. 11 may be fitted on the front surface of the module substrate 30. This configuration provides double electromagnetic shielding effect with respect to the high-frequency circuit component 32 or components 32a-32d mounted on the rear surface (i.e., soldering side) of the module substrate 30 by means of a not shown GND plane (or power supply plane) of the module substrate 30 and shield case. The box-like frame 10 shown in FIG. 1 may be used as the shield cap to be fitted on the module substrate 30. Further, although the frame-like portion of the frame has a rectangular shape in the above embodiments, it may be formed into a cylindrical shape or a polygonal shape.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a frame comprising a hollow portion inside of the frame;
a shield coating applied to an inner surface of the frame;
a plurality of connection terminals comprising lead portions provided on an outside surface of the frame; and
a module substrate with circuit components mounted on front and rear surfaces of the module substrate and connected to the connection terminals, the module substrate placed on the frame where rear side circuit components are housed in the hollow portion.

2. The electronic apparatus of claim 1, wherein
the frame comprises a support structure for supporting the module substrate, and
the connection terminals are formed such that edge portions of the connection terminals are exposed on an edge surface of the frame, and the circuit components are connected to the connection terminals when the module substrate is placed on the frame.

3. The electronic apparatus of claim 2, wherein
the frame has an open portion on a first side of the frame and a closed portion on a second side of the frame, and
the open portion is closed by the module substrate.

4. The electronic apparatus of claim 3, wherein
the frame and the closed portion are integrally formed into a box-like shape casing with the closed portion as the bottom surface.

5. The electronic apparatus of claim 4, wherein
the shield coating is applied to an inner surface of the casing by metal plating, and
the circuit components mounted on the rear surface of the module substrate are housed in the casing such that they are electro-magnetically shielded by the shield coating.

6. The electronic apparatus of claim 1, wherein
the frame is mounted on an integrated substrate employing the module substrate as a mounting component, and
the module substrate is circuit-connected to the integrated substrate through the connection terminals on the frame.

7. The electronic apparatus of claim 6, wherein
the frame is configured to electromagnetically shield the circuit components mounted on the rear surface of the module substrate by the inner surface of the frame with the shield coating; and
the module substrate is configured to connect to the integrated substrate by the connection terminals on the outer surface of the frame.

8. The electronic apparatus of claim 7, wherein
the shield coating is conductively connected to a ground terminal comprised in the plurality of connection terminals and is connected to a ground pattern of the integrated substrate through the ground terminal.

9. The electronic apparatus of claim 1, wherein
the frame comprises a plurality of frame-like portions, and
the shield coating is applied to an inner surface of at least one frame-like portion.

10. A substrate mounting method for mounting a module substrate to an integrated substrate, comprising:
mounting circuit components on the front and rear surfaces of the module substrate;
interposing a frame comprising a hollow portion applied with an electromagnetic shield inside the frame and a plurality of connection terminals on the outer surface of the frame between the module substrate and the integrated substrate;
housing at least the circuit components on the rear surface of the module substrate in the hollow portion of the frame; and
electro-magnetically shielding the circuit components mounted on the rear surface of the module substrate by the electromagnetic shield in the inner surface portion of the frame and connecting the module substrate to the integrated substrate by the connection terminals on the outer surface of the frame.
